(19) United States
(12) Patent Application Publication
(10) Pub. No.: US 2008/0157880 A1
(43) Pub. Date: Jul. 3, 2008

(54) TEMPERATURE COMPENSATED LOOP FILTER

(76) Inventors: Eyal Fayneh, Givatyim (IL); Ernest Knoll, Haifa (IL)

Correspondence Address: INTEL/BLAKELY, 1279 OAKMEAD PARKWAY, SUNNYVALE, CA, 94085-4040, US

(21) Appl. No.: 11/618,466

(22) Filed: Dec. 29, 2006

(51) Int. Cl. H03L 7/08; G05D 23/20

(52) U.S. Cl. 331/17; 331/66

(57) ABSTRACT

Disclosed herein are embodiments of a temperature compensating solution to reduce changes in PLL damping factor that would otherwise occur with changes in temperature.

### BACKGROUND

The present invention relates generally to a loop filter, e.g., for a phase locked loop (PLL) circuit. For example, they may be used in data link clocks or to generate a CPU domain clock. In particular, it pertains to temperature compensation solutions for stabilizing the damping factor in a PLL.

In PLLs such as so called non self-biased PLLs, the damping factor (which is proportional to charge-pump current and loop filter resistance) can widely vary with temperature. Unfortunately, damping factor variations adversely affect PLL response to noise sources such as reference signal phase noise, VCC phase noise and feedback-network power supply noise. As a result, the quality of the PLL output signal may degrade. Since temperature typically changes dynamically during chip operation, PLL performance changes accordingly. Therefore, to attain stable PLL operation, damping factor variations due to changes in temperature should be reduced.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a diagram generally showing a typical, non self-biased phase locked loop circuit.

FIG. 2 is a diagram showing an active loop filter for a PLL.

FIG. 3 is a graph showing the affects of temperature change on loop filter resistance and charge pump current in a PLL circuit.

FIG. 4 is a diagram of an active loop filter with temperature compensation in accordance with some embodiments.

FIG. 5 is a diagram of a conventional temperature compensating reference generator circuit.

FIG. 6 is a graph showing charge pump current and loop filter resistance, as a function of temperature, for an active loop filter circuit with temperature compensation in accordance with some embodiments.

FIG. 7 is a graph showing charge pump current times loop filter resistance, as a function of temperature, for active loop filter circuits with and without temperature compensation in accordance with some embodiments.

FIG. 8 is a block diagram of a computer system having a microprocessor with at least one PLL circuit with a temperature compensated active loop filter in accordance with some embodiments.

### DETAILED DESCRIPTION

Presented herein are novel techniques to compensate for PLL damping factor variations due to temperature variations In some embodiments, PLL response may be stabilized for wide temperature variations, As a result, PLL jitter performance may also be improved.

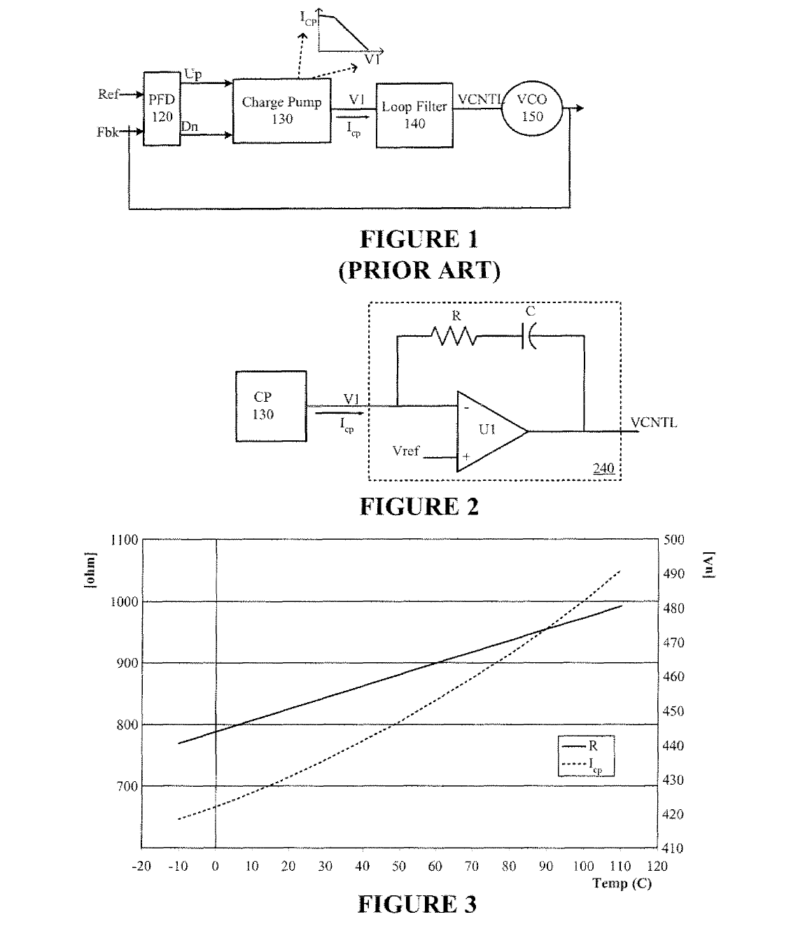

FIG. 1 generally shows an exemplary non self-biased phase locked loop (PLL) circuit. It comprises a phase-frequency detector 120, a charge pump 130, a loop filter 140, and a voltage-controlled oscillator 150, coupled together as shown. The charge pump 130 is a self-biased charge pump with a downwardly sloping charge pump current response. An example of such a charge pump circuit is described in U.S. Pat. No. 6,894,569 to Fayneh et al., entitled: HIGH-PERFORMANCE CHARGE PUMP FOR SELF-BIASED PHASE-LOCKED LOOP, incorporated by reference herein.

The phase-frequency detector compares a reference signal REF and a feedback signal FBK to determine whether a frequency and/or phase difference exists between them. The feedback signal may directly correspond to the output of the voltage-controlled oscillator or may constitute a divided version of this output, achieved, e.g., by placing a divider circuit in a feedback path connecting the VCO and phase-frequency detector.

In operation, the phase-frequency detector determines whether a phase (or frequency) difference exists between the reference and feedback signals. If a difference exists, the detector outputs one of an Up signal and a Down signal to control the output of the charge pump. If the phase of the reference signal leads the phase of the feedback signal, the charge pump sources current to the loop filter to cause the VCO to advance the output phase/frequency. Conversely, if the phase of the reference signal lags the phase of the feedback signal, the charge pump sinks current from the loop filter to cause the VCO to reduce the output signal phase/frequency.

The amount of time current is sourced to or sinked from the loop filter corresponds to the width of the pulse of Icy. Since the width of this pulse is proportional to the phase/frequency difference between the reference and feedback signals, the loop filter will charge/discharge for an amount of time that will bring the phases of these signals into coincidence. The resulting signal output from the loop filter will therefore control the VCO to output a signal at a frequency and a phase which is not substantially different from the reference signal input into the phase-frequency detector.

With reference to FIG. 2, an active loop filter 240 is shown. It comprises an amplifier U1 resistor R, and capacitor C, all coupled together as shown. Resistor R may comprise a passive resistor formed from a relevant semiconductor process, e.g., an N-well resistor in a MOS semiconductor process. The resistor R and capacitor C are coupled together in series between the amplifier output terminal (VCNTL) and its negative input terminal, thereby providing a frequency-dependent negative feedback path for the amplifier. A reference voltage (Vref) is coupled to its positive input terminal. With a amplifier gain of G, the value of V1 is, V1=VCNTL/G+Vref. Thus, when the amplifier has a relatively high gain, it forces the voltage at its negative input (V1) to approach the reference voltage (Vref).

The charge pump 130 drives the filter 240 to generate the control voltage -VCNTL) for the VCO. The charge pump drives current into the loop filter to charge it, or sinks current from the loop filter to discharge it. For a given amount of time (ΔT) that I_{CP} is at a particular value (which is a function of the charge pump output voltage (V1), the filter output voltage is: VCNTL=V₀+RI_{CP}+(I_{CP}ΔT)/C, where Vo is the initial voltage charge across the capacitor.

The peak voltage of VCNTL determines the PLL damping factor. The peak voltage is primarily determined by I_{CP}R. Thus, if I_{CP} and R varies with temperature, so to does the PLL damping factor.

FIG. 3 shows the natural behavior of a resistor R (e.g., GBNWELL resistor) and the charge pump current versus temperature for the filter of FIG. 2 in accordance with some embodiments, The characteristics were measured by setting Vref to a constant voltage over the indicated temperature range. As it can be seen in the graph, I_{CP} and R vary in direct proportion with the temperature. Thus, the product (I_{CP}R) increases with rising temperature, thereby causing the PLL damping factor to also rise.

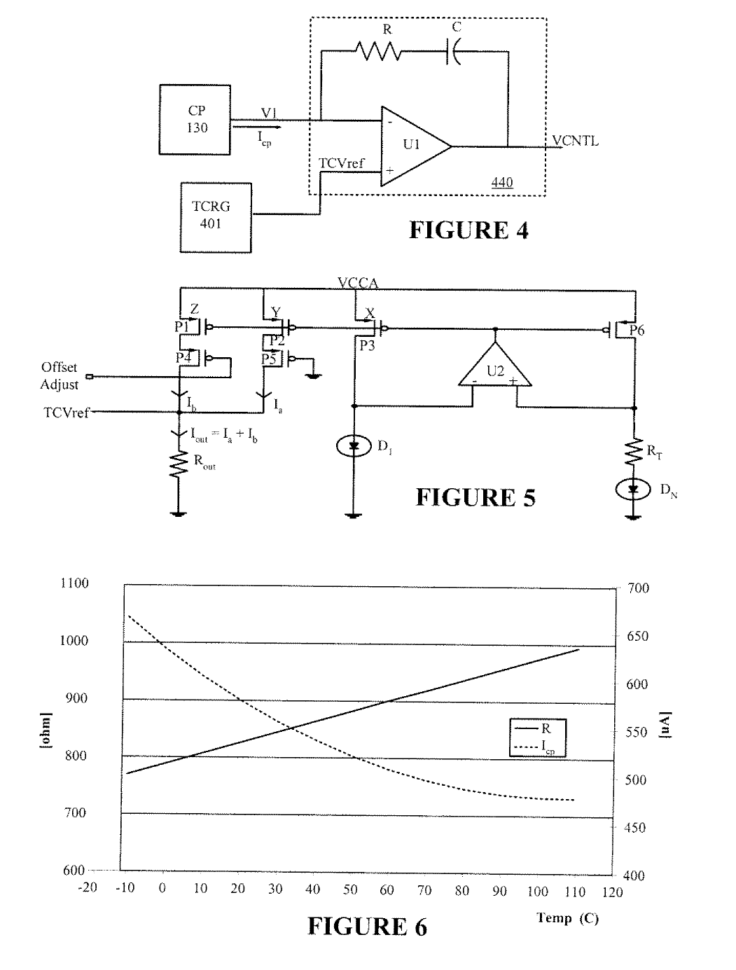

FIG. 4 shows an active filter with temperature compensation in accordance with some embodiments. It comprises an amplifier U1, resistor R, and capacitor C, configured as discussed above with respect to FIG. 2. However, instead of using a fixed reference (Vref), it uses as its reference voltage a varying, temperature compensating voltage reference (TCVref) generated by a temperature compensating reference generator (TCRG) 401.

The TCRG circuit 401 generates a temperature dependent reference voltage and provides it to the amplifier as shown, Since the gain of the amplifier is high, the voltage V1 at the output of the charge pump follows the TCVref voltage. In the depicted embodiment, the TCVref signal increases with temperature thereby causing V1 to also increase with temperature. This causes the charge pump current I_{CP} to decrease with temperature, countering the increase due to temperature increases, as well as the increase in the resistance of R. (It should be appreciated that any suitable circuit to generate a temperature compensating reference may be used to appropriately limit an increase in charge pump current and/or loop filter resistance as temperature increases. An example of such a suitable circuit is described in the following section.)

FIG. 5 shows a conventional temperature compensating reference generating circuit, suitable for use as TCRG circuit 401. It generally comprises resistors Rₒᵤₜ, R_{T}; PMOS transistors P1 to P6; amplifier U2; and diodes D₁ and D_{N}, all coupled together as shown. Diode D_{N} is N times larger than D₁ and thus has a smaller voltage dropped across it. Because amplifier U2 is configured with negative feedback, it forces the voltages at its input terminals (+, −) to be substantially equivalent. Accordingly, in view of the relative affect that temperature change has on D_{N} and D₁, a voltage is dropped across R_{T} that is substantially linearly proportional to the ambient temperature of the circuit. This voltage drop proportionally controls the current in P6 which in effect is mirrored to P2 and P1 (if engaged).

Thus, the current (Iₒᵤₜ=Iₐ+I_{b}) generated in P2 and P1 (when engaged) is proportional to the circuit temperature. In turn, the voltage, TCVref, across Rₒᵤₜ will be indicative of the circuit temperature and thus control the charge pump output voltage, and hence the charge pump output current, based on the temperature. Note that the actual TCVref voltage level can be calibrated by setting the current ratio Y/X to a desired value.

In the depicted embodiment, the temperature compensating reference generator circuit includes an offset adjustment feature to increase or decrease, on a stepwise basis, the TCVref voltage. This may be used, for example, to calibrate the TCVref voltage. This is achieved with temperature dependent current source transistor P1, which is engaged or disengaged by P2 based on the state of a temperature band select signal (Offset Adjustment). When Offset Adjustment is asserted, the current from the switched current source P1 is added to the current from current source P2. This changes the level of the TCVref voltage in a step. When P1 is engaged, TCVref “steps” upward.

FIG. 6 shows the behavior of a resistor R and the charge pump current versus temperature for an embodiment of the circuit of FIG. 4. As it can be seen, the charge pump current behavior versus temperature is now inverted with regard to FIG. 3. I_{CP} varies in indirect proportion with the temperature while R varies in direct proportion with the temperature, making the product I_{CP}R to be almost constant versus temperature thereby making more stable the PLL damping factor.

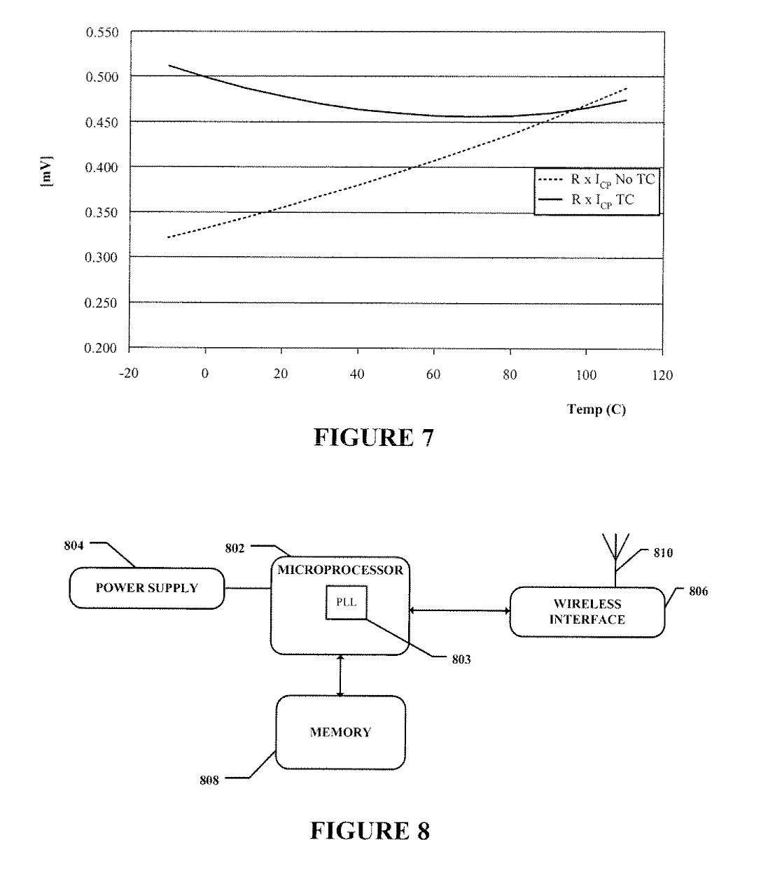

For the PLL embodiment used with regard to FIG. 6, FIG. 7 shows the product I_{CP}R versus temperature for an active filter with and without temperature compensation. Without temperature compensation, the I_{CP}R product varies by a factor of about 1.5 over a temperature range from −10 to 110 deg. C. On the other hand, with temperature compensation, the I_{CP}R product varies by only a factor of about 1.1 over the same temperature range. In some embodiments, this may translate to an improvement of 36% in the damping factor stability versus temperature.

With reference to FIG. 8, one example of a computer system is shown. The depicted system generally comprises a processor 802 that is coupled to a power supply 804, a wireless interface 806, and memory 508. It is coupled to the power supply 804 to receive from it power when in operation. The wireless interface 806 is coupled to an antenna 810 to communicatively link the processor through the wireless interface chip 806 to a wireless network (not shown). Microprocessor 802 comprises one or more PLL circuits 803, such as the circuit of FIG. 1 with temperature compensated charge pump and loop filter such as the one of FIG. 4.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. An integrated circuit, comprising;
a charge pump circuit to generate a charge pump output current; and
a loop filter circuit to generate a VCO control voltage based on the output charge pump current, the loop filter to counter changes in the charge pump output current that otherwise would occur due to changes in temperature.

2. The integrated circuit of claim 1, in which the loop filter comprises an amplifier with a reference input coupled to a temperature compensated voltage reference signal.

3. The integrated circuit of claim 2, in which the charge pump circuit generates an output voltage that is inversely proportional to the generated output current, the temperature compensated reference voltage signal to cause the charge pump output voltage to change with changes in temperature.

4. The integrated circuit of claim 3, in which the charge pump is a self-biased charge pump.

5. The integrated circuit of claim 4, in which the loop filter comprises a resistor and capacitor coupled between an inverting input of the amplifier and an amplifier output providing the VCO control voltage.

6. The integrated circuit of claim 5, in which the resistor is an N-well type MOS process resistor.

7. A PLL circuit comprising the charge pump circuit and loop filter circuit of claim 1, the PLL being a non-biased PLL.

8. A method comprising:
generating a charge pump current to generate a VCO control voltage; and
countering the change in charge pump current that would otherwise occur due to temperature change.

9. The method of claim 8, in which a charge pump output voltage is generated, said charge pump output voltage affecting the charge pump output current.

9. The method of claim 8, in which countering comprises changing the charge pump output voltage in response to temperature change.

10. The method of claim 9, in which charge pump output voltage is changed by changing a temperature compensated reference to an amplifier.

11. The method of claim 10, in which the charge pump current changes inversely proportional to the charge pump output voltage.

12. The method of claim 8, in which the act of countering is implemented in an active loop filter.

13. A computer system, comprising:
a microprocessor having a PLL with a charge pump circuit to generate a charge pump output current, and a loop filter circuit to generate a VCO control voltage based on the output charge pump current, the loop filter to counter changes in the charge pump output current that otherwise would occur due to changes in temperature; and
an antenna coupled to the microprocessor to communicatively link it with a wireless network.

14. The computer system of claim 13, in which the loop filter comprises an amplifier with a reference input coupled to a temperature compensated voltage reference signal.

15. The computer system of claim 14, in which the charge pump circuit generates an output voltage that is inversely proportional to the generated output current, the temperature compensated reference voltage signal to cause the charge pump output voltage to chance proportionally to changes in temperature.

16. The computer system of claim 1S, in which the charge pump is a self-biased charge pump.

17. The computer system of claim 16, in which the loop filter comprises a resistor and capacitor coupled between an inverting input of the amplifier and an amplifier output providing the VCO control voltage.

18. The computer system of claim 17 in which the resistor is an N-well type MOS process resistor.
